(19) United States
(12) Patent Application Publication
(10) Pub. No.: US 2020/0357766 A1
(43) Pub. Date: Nov. 12, 2020

(54) SEMICONDUCTOR PACKAGES WITH ADHESION ENHANCEMENT LAYERS

(71) Applicant: NANYA TECHNOLOGY CORPORATION, New Taipei City (TW)

(72) Inventor: Kuo-Hui SU, TAIPEI CITY (TW)

(21) Appl. No.: 16/407,753

(22) Filed: May 9, 2019

(51) Int. Cl. H01L 25/065; H01L 23/31; H01L 23/16; H01L 23/538

(52) U.S. Cl. CPC H01L 25/0652; H01L 23/3135; H01L 2225/06541; H01L 23/16; H01L 23/538; H01L 23/3128

(57) ABSTRACT

A semiconductor package includes a plurality of intermediate dies and an encapsulant layer. The intermediate dies are stacked on a base die, in which the edge regions of the base die are exposed. The encapsulant layer is disposed to cover side surfaces of the intermediate dies as well as a surface of the exposed edge regions of the base die. The surface of the edge regions of the base die includes an adhesion enhancement layer.

### TECHNICAL FIELD

The present disclosure relates to semiconductor packages, and more particularly, to semiconductor packages including stacked dies and adhesion enhancement layers.

### DISCUSSION OF THE BACKGROUND

The semiconductor industry continues to improve the integration density of various electronic components (e.g., transistors, diodes, resistors, capacitors, etc.) by continual reductions in minimum feature size, which allow more components to be integrated into a given area. Multi-chip stacked packaging techniques and/or system in package techniques have been in demand with the development of multi-functional electronic systems and the greater storage capacity of smaller electronic systems or products. In addition, in order to achieve a fast signal transmission speed, a high bandwidth solution is required. Although a plurality of chips are stacked in a semiconductor package, much effort has been focused on reducing the size of the semiconductor package. As package size decreases, delamination defects, where the encapsulant of the semiconductor package detaches from the semiconductor dies, need to be addressed.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor package. The semiconductor package includes a plurality of intermediate dies and an encapsulant layer. The intermediate dies are stacked on a base die, such that the edge regions of the base die are exposed. The encapsulant layer is disposed to cover side surfaces of the intermediate dies as well as a surface of the exposed edge regions of the base die. The surface of the edge regions of the base die includes an adhesion enhancement layer.

In some embodiments, the adhesion enhancement layer has one or more gaps at least partially filled by the encapsulant layer.

In some embodiments, the adhesion enhancement layer includes a hydrophilic material.

In some embodiments, the hydrophilic material is silicon dioxide.

In some embodiments, the adhesion enhancement layer includes a hydrophobic material.

In some embodiments, the hydrophobic material is selectively formed on different portions of the adhesion enhancement layer.

In some embodiments, the hydrophobic material is a carbon-based material.

In some embodiments, the side surfaces of the base die are vertically aligned with outer side surfaces of the encapsulant layer, respectively.

In some embodiments, the base die and the intermediate dies form a high bandwidth memory (HBM) device.

In some embodiments, the base die and the intermediate dies are electrically connected to each other by through silicon vias (TSVs).

Another aspect of the present disclosure provides a semiconductor package. The semiconductor package includes a first semiconductor package, an interconnect layer, and a semiconductor device. The first semiconductor package includes a plurality of intermediate dies and a first encapsulant layer. The intermediate dies are stacked on a base die, such that the edge regions of the base die are exposed. The first encapsulant layer is disposed to cover side surfaces of the intermediate dies as well as a surface of the exposed edge regions of the base die. The surface of the edge regions of the base die includes an adhesion enhancement layer. The first semiconductor package is mounted on the interconnect layer. The semiconductor device is disposed on the interconnect layer and beside the first semiconductor package. The semiconductor package further includes a second encapsulant layer covering the first semiconductor package and the semiconductor device.

In some embodiments, the adhesion enhancement layer has one or more gaps at least partially filled by the first encapsulant layer.

In some embodiments, the adhesion enhancement layer comprises a hydrophilic material.

In some embodiments, the hydrophilic material is silicon dioxide.

In some embodiments, the adhesion enhancement layer comprises a hydrophobic material.

In some embodiments, the hydrophobic material is selectively formed on different portions of the adhesion enhancement layer.

In some embodiments, the hydrophobic material is a carbon-based material.

In some embodiments, the side surfaces of the base die are vertically aligned with outer side surfaces of the first encapsulant layer, respectively.

In some embodiments, the base die and the intermediate dies form a high bandwidth memory (HBM) device.

In some embodiments, the base die and the intermediate dies are electrically connected to each other by through silicon vias (TSVs).

Since the material of the adhesion enhancement layer is selected based on the encapsulant layer and the design characteristics of the semiconductor package, the strength of adhesion between the encapsulant layer and the base die is optimized. Matching a hydrophilic encapsulant layer with a hydrophilic adhesion enhancement layer, or a hydrophobic encapsulant layer with a hydrophobic adhesion layer, decreases the likelihood of the base die detaching from the encapsulant layer and causing a delamination issue. Moreover, by introducing gaps in the adhesion enhancement layer and forming trench structures, the adhesion interface area is maximized. The encapsulant layer may protrude into the trench structures to serve as anchors for the semiconductor package, thereby minimizing the stress, which may cause the delamination issue.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a cross-sectional view depicting a semiconductor package in accordance with some embodiments of the present disclosure;

FIG. 2 is an enlarged view of a portion K of FIG. 1 in accordance with some embodiments of the present disclosure;

FIG. 3 is an enlarged view of a portion K of FIG. 1 in accordance with some embodiments of the present disclosure;

FIG. 4 is a cross-sectional view depicting a semiconductor package corresponding to a system-in-package in accordance with some embodiments of the present disclosure;

FIG. 5 is a block diagram depicting an electronic system including a memory card employing at least one of the semiconductor packages according to some embodiments of the present disclosure;

FIG. 6 is a block diagram depicting an electronic system including at least one of the semiconductor packages according to some embodiments of the present disclosure.

### DETAILED DESCRIPTION

The following description of the disclosure accompanies drawings, which are incorporated in and constitute a part of this specification, and illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

The present disclosure is directed to semiconductor packages including stacked dies and adhesion enhancement layers. In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure are described in detail below. However, in addition to the detailed description, the present disclosure may also be widely implemented in other embodiments. The scope of the present disclosure is not limited to the detailed description, but is defined by the claims.

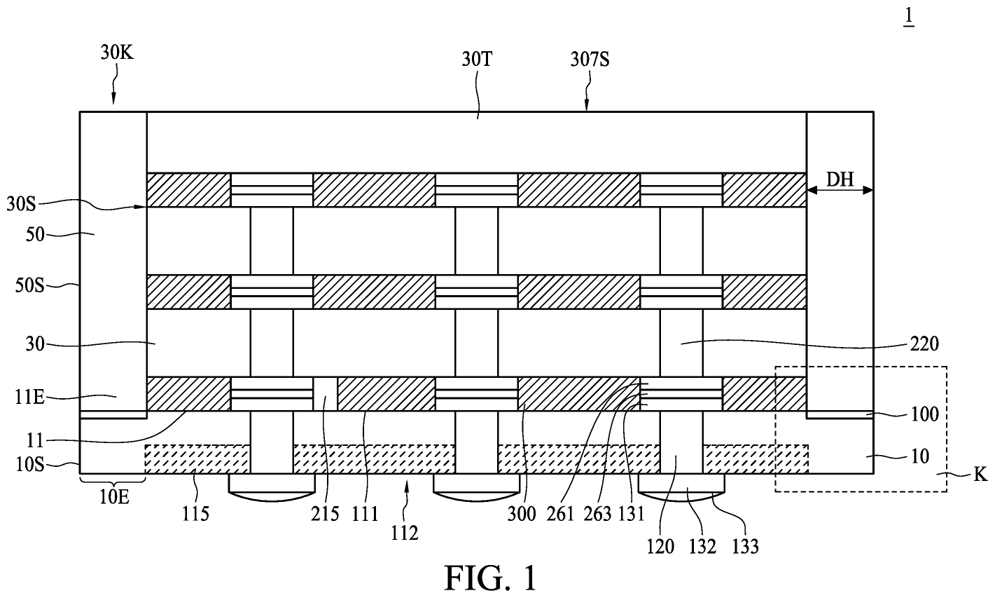

In accordance with some embodiments of the disclosure, FIG. 1 depicts a cross-sectional view of a semiconductor package. As shown in FIG. 1, a semiconductor package 1 may include a base die 10 and intermediate dies 30 stacked on the base die 10. The intermediate dies 30 may have substantially a same width, although in some embodiments, the base die 10 may have a width greater than the widths of the intermediate dies 30. The edge regions 10E of the base die 10 may laterally protrude beyond side surfaces of the intermediate dies 30. The intermediate dies 30 may be vertically stacked on a first surface 11 of the base die 10 such that the edge surfaces 11E of the edge regions 10E of the base die 10 are exposed. The first surface 11 may be a backside surface of the base die 10, for example. The edge surfaces 11E of the base die 10 may be part of the first surface 11 of the base die 10.

In some embodiments, the semiconductor package 1 may also include an encapsulant layer 50. The encapsulant layer 50 may be disposed to cover the edge surfaces 11E of the base die 10 and side surfaces 30S of a stack 30K of the intermediate dies 30. The encapsulant layer 50 may be disposed to leave a top surface 307S of a topmost intermediate die 30T of the intermediate die stack 30K exposed. Since the encapsulant layer 50 leaves the top surface 30TS of the topmost intermediate die 30T exposed, heat generated by operation of the intermediate dies 30 may be efficiently removed so as to maintain the performance of the semiconductor package 1. The encapsulant layer 50 may cover a surface of the exposed edge regions 10E of the base die 10. In some embodiments, although not shown in the Figures, the encapsulant layer 50 may further extend over a top surface 40TS to cover the top surface 40TS and side surfaces 40S of an intermediate die stack 40K.

When the size of the semiconductor package 1 is reduced, a width DH of the encapsulant layer 50 may be decreased. The width DH of the encapsulant layer 50 may correspond to a distance between the side surface 30S of the intermediate core stack 30K and an outer side surface 505 of the encapsulant layer 50. In some embodiments, the outer side surface 505 of the encapsulant layer 50 may be vertically aligned with a side surface 10S of the base die. The outer side surface 505 of the encapsulant layer 50 and the side surface 505 of the base die 10 may form a side surface of the semiconductor package 1. Accordingly, the width DH of the encapsulant layer 50 may correspond to a width of the edge region 10E of the base die 10. Since the width of the edge region 10E of the base die 10 may be less than a total width of the base die 10, the width DH of the encapsulant layer 50 may be narrow compared to the total width of the base die 10.

The edge surfaces 11E of the base die 10 may have a substantially flat profile. In some cases, the planar area of an interface surface between the encapsulant layer 50 and the edge surfaces 11E of the base die 10 may be minimized to reduce an adhesive strength between the encapsulant layer 50 and the base die 10. If the adhesive strength between the encapsulant layer 50 and the base die 10 is reduced, the encapsulant layer 50 may not be securely fastened to the base die 10. As such, the base die 10 may become separated from the encapsulant layer 50 after some time, leading to a delamination issue in the semiconductor package 1.

In some embodiments, the edge surfaces 11E of the base die 10 may include an adhesion enhancement layer 100. The adhesion enhancement layer 100 may include features that increase the bonding strength between the encapsulant layer 50 and the base die 10.

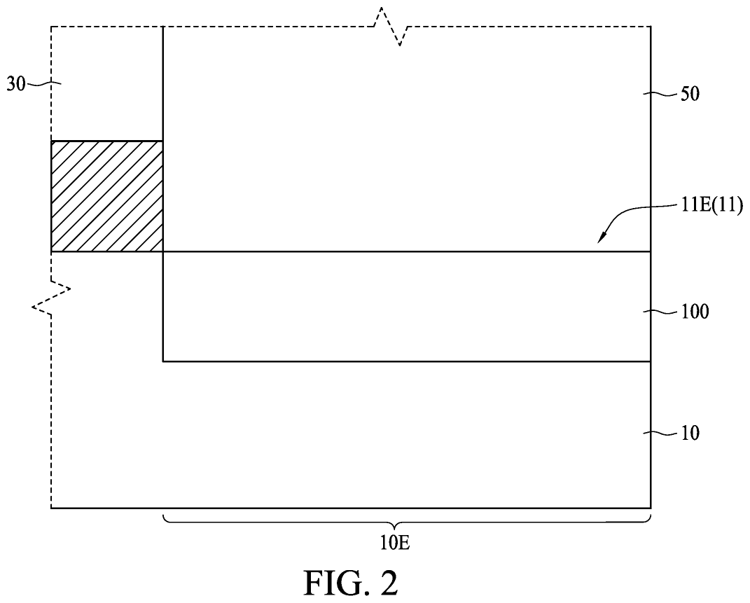

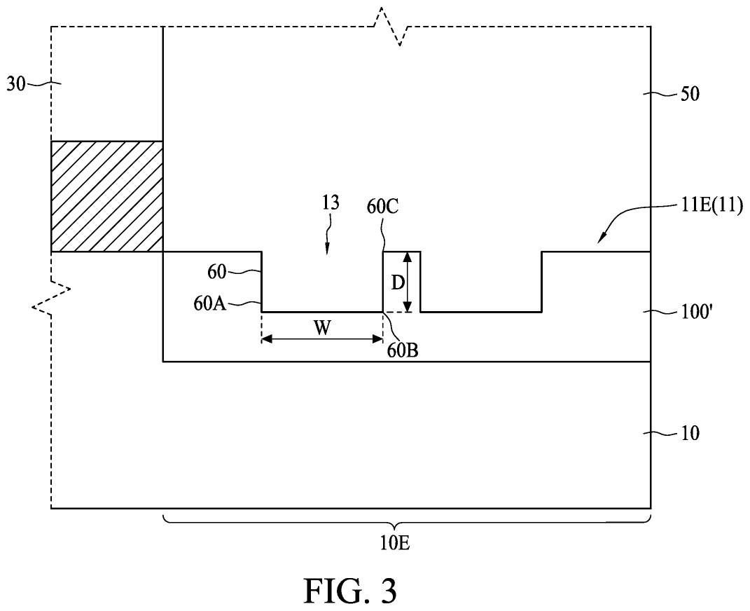

FIG. 2 and FIG. 3 depict enlarged views of a portion K of FIG. 1 in accordance with some embodiments of the present disclosure. As shown in FIG. 2, the edge surface 11E of the base die 10 includes the adhesion enhancement layer 100. The composition of the adhesion enhancement layer 100 may depend on the encapsulant layer 50 as well as other design characteristics of the semiconductor package 1. For example, in some embodiments, the adhesion enhancement layer 100 includes a hydrophilic material such as silicon dioxide, or mixtures thereof, for the enhancement of bonding strength between the encapsulant layer 50 and the base die 10. In this example, since the encapsulant layer 50 may also be made of a hydrophilic material, the silicon dioxide adhesion enhancement layer 100 promotes adhesion and may mitigate the delamination issue of the semiconductor package 1. The adhesion enhancement layer 100 of the edge surface 11E in this example may be formed by oxidizing the silicon of the edge surfaces 11E of the base die 10, such as by contacting the base die 10 with an ozone-containing gas mixture, or by contacting the base die 10 with a liquid solution containing water and ozone. The adhesion enhancement layer 100 formed may be at least 5 angstroms thick, for example. The adhesion enhancement layer 100 may be formed before the encapsulant layer 50 is applied to the semiconductor package 1. Accordingly, the adhesion enhancement layer 100 is a hydrophilic layer having high surface energy, which may be primarily terminated by oxygen residues. The encapsulant layer 50 used in these examples may be comprised of polyimide compounds such as bismaleimide (BMI), for instance. Another example of a suitable material for the encapsulant layer 50 includes epoxy adhesives used in semiconductor manufacturing, containing at least a portion of a silane coupling agent. The typical silane compound used in such material is composed of a silicon atom bonded to one or more hydroxyl residues and one or more hydrocarbon chains.

In some embodiments, the formation of the silicon dioxide adhesion enhancement layer 100 may be further combined with a curing process of the encapsulant layer 50, which may occur in a solder reflow oven, wire bonding machine, or any apparatus suitable for incubating the semiconductor package 1 at a preferred temperature for the application. In some embodiments, if the encapsulant layer 50 is made of a silane-containing adhesive, the hydrophilic silicon dioxide adhesion enhancement layer 100 reacts with the silane-containing encapsulant layer 50 during the curing process to increase the strength of adhesion. During the curing process, the hydroxyl groups of the encapsulant layer 50 may react with the adhesion enhancement layer 100 to form a siloxy lattice where the silicon atoms are linked to one another through oxygen atoms. Such lattice formation with the silicon dioxide adhesion enhancement layer 100 may achieve faster reaction times and deeper silane penetration, thus reducing the curing time of the semiconductor package 1 while also increasing the adhesion strength. Moreover, the hydrophilic silicon dioxide adhesion enhancement layer 100 may also prevent the base die 10 from sticking to pick-up tips in automated semiconductor processes, thereby increasing the yield rate of the semiconductor package 1.

It should be noted that other suitable processes for oxidizing the silicon of the edge surfaces 11E of the base die 10, as well as other suitable processes for depositing the silicon dioxide of the adhesion enhancement layer 100, may be used, and the present disclosure is not limited to any specific process as long as the required thickness of silicon dioxide is produced. Moreover, it should be further noted that the adhesion enhancement layer 100 may be made of other hydrophilic is materials, such as hydrophilic compounds containing hydroxyl residues along with the oxygen residues.

In some embodiments, the encapsulant layer 50 may be a hydrophobic adhesive so as to satisfy some applications of the semiconductor package 1. In these embodiments, the adhesion enhancement layer 100 may include a hydrophobic material, such as a carbon-based material. The hydrophobic adhesion enhancement layer 100 may include hydrogen terminated silicon, carbon, germanium, or mixtures thereof, for example. The hydrophobicity of the adhesion enhancement layer 100 may be controlled by selectively forming the hydrophobic material on different portions of the adhesion enhancement layer 100, depending on the type of encapsulant layer 50 used and the application of the semiconductor package 1. The hydrophobic material of the adhesion enhancement layer 100 may be selectively formed at predetermined intervals along the edge surfaces 11E of the base die 10, selectively formed in a stepwise manner along the edge surfaces 11E of the base die 10, or selectively formed in any suitable manner according to the type of encapsulant layer 50 used and the application of the semiconductor package 1.

It should be noted that, in some embodiments, the adhesion enhancement layer may have one or more gaps at least partially filled by the encapsulant layer 50, so as to increase an interface area between the encapsulant layer and the base die 10 and to increase the strength of adhesion. FIG. 3 depicts an enlarged view of the portion K of FIG. 1 in accordance with another embodiment of the present disclosure. As shown in FIG. 3, the gaps 13 in an adhesion enhancement layer 100′ are formed by a plurality of trench structures 60. The gaps 13 have a width W, and the gaps 13 are filled at least partially by the encapsulant layer 50 extending or protruding into the trench structures 60. Portions of the encapsulant layer 50 protruding into the trench structures may serve as anchors for the semiconductor package 1 while minimizing the likelihood of the delamination issue. The width W may be on the order of tens of micrometers, for example. The trench structures 60 have a depth D, which may be determined according to a thickness of the base die 10. The trench structures 60 may extend in a direction that is parallel with each of the side surfaces 30S of the intermediate die stack 30K. The trench structures 60 may be fabricated by a wet etch process, a plasma etch process, or other suitable semiconductor fabrication processes. It should be noted that the gaps 13 of the adhesion enhancement layer 100′ may or may not have the same width W.

As previously described for the adhesion enhancement layer 100 of FIG. 2, the material of the adhesion enhancement layer 100′ may depend on the encapsulant layer 50 or the application of the semiconductor package 1, so as to maximize the adhesion strength between the encapsulant layer 50 and the base die 10. For instance, when the encapsulant layer 50 is a hydrophilic adhesive, the adhesion enhancement layer 100′ may include a hydrophilic material, such as silicon dioxide or mixtures thereof. When the encapsulant layer 50 is a hydrophobic adhesive, the adhesion enhancement layer 100′ may include a hydrophobic material, such as a carbon-based material, for example. Moreover, the hydrophobic material may also be selectively formed on different portions of the adhesion enhancement layer 100′. For example, the hydrophobic material may be selectively formed on sidewalls 60A, 60B, and 60C of the trench structures 60 to further increase adhesion strength. Accordingly, the portions of the encapsulant layer 50 protruding into the trench structures 60 may serve as anchors for the semiconductor package 1 while minimizing the stress that typically causes a delamination issue, wherein the encapsulant layer 50 is detached from the base die 10.

With reference to FIG. 1 again, the base die 10 may include a plurality of through silicon vias (TSVs). In some embodiments, the base die 10 may include a semiconductor body layer, and circuit elements may be integrated in or on the semiconductor body layer. A first through via 120 may be disposed to vertically penetrate the semiconductor body layer, which may be a silicon layer, of the base die 10. The first connection terminals 122 may be disposed on a second surface 112 of the base die 10 opposite to the intermediate die stack 30K, for electrically connecting the base die 10 to an external device. The second connection terminals 131 may be disposed on a first surface 111 of the base die 10. The second connection terminals 131 may electrically connect the base die 10 to the intermediate die stack 30K.

In some embodiments, a surface on which the first connection terminals 132 are disposed may be different from a surface on which the second connection terminals 131 are disposed. The first connection terminals 132 may be disposed to overlap with the first through vias 120, respectively. The second connection terminals 131 may also be disposed to overlap with the first through vias 120, respectively. The first connection terminals 132 may be disposed to respectively overlap with the second connection terminals 131 in a plan view. The first connection terminals 132 may be electrically connected to the first through vias 120, respectively. The second connection terminals 131 may also be electrically connected to the first through vias 120, is respectively. Accordingly, signal paths including the first connection terminals 132, the first through vias 120, and second connection terminals 131 may be provided. The signal paths may be disposed to pass through the base die 10.

In some embodiments, the first connection terminals 132 may be bumps protruding from the second surface 112 of the base die 10. Each of the bumps corresponding to the first connection terminals 132 may include copper. A first conductive adhesive layer 133 may be disposed on ends of the first connection terminals 132 opposite to the base die 10. The first conductive adhesive layer 133 may include a solder layer. The solder layer used as the first conductive adhesive layer 123 may include an alloy of silver (Ag) and tin (Sn). A barrier layer such as a nickel layer may be additionally disposed between the first conductive adhesive layer 133 and the first connection terminals 132. The second connection terminals 131 may be copper bumps protruding from the first surface 111 of the base die 10. The base die 10 may include an active layer 115 adjacent to the second surface 112, the active layer 115 including circuit elements constituting an integrated circuit. Each of the intermediate dies 30 may have a function different from a function of the integrated circuit formed in the base die 10. For example, the intermediate dies 30 may be memory devices, and the integrated circuit of the base die 10 may include a controller for controlling operations of the intermediate dies 30. In some embodiments, the intermediate dies 30 are memory devices having a substantially same feature and function, and the semiconductor package 1 may have a large memory capacity.

In some embodiments, the semiconductor package 1 may be configured such that the base die 10 and the intermediate dies 30intermediate die may constitute a high bandwidth memory (HBM) structure. Each of the intermediate dies 30 may be a DRAM device including banks storing data, and the base die 10 may include a test circuit for the intermediate dies 30 and a circuit for soft-repairing the intermediate dies 30. That is, the base die 10 may output an address and a command for performing a read operation and a write operation of the intermediate dies 30, which may be DRAM devices. The base die 10 may include an interface having a physical layer (PHY) for signal transmission between the base die 10 and the intermediate dies 30 or between the base die 10 and an external device. The base die 10 may be electrically connected to the intermediate dies 30 through the TSVs that are disposed to penetrate the intermediate dies 30 and the base die 10.

Second through vias 210 may be disposed to vertically penetrate each of the intermediate dies 200. A third connection terminal 252 and a fourth connection terminal 251 may be disposed on both ends of each of the second through vias 210, respectively. If the third connection terminal 252 is disposed on one surface of a certain die of the intermediate dies 200, the fourth connection terminal 251 may be disposed on another surface of the certain die of the intermediate dies 200. Thus, signal paths including the third connection terminals 152, the second through vias 210, and the second connection terminals 151 may be provided in the intermediate die stack 200C. The signal paths may be disposed to pass through the intermediate dies 200. Each of the third and fourth connection terminals 152 and 151 may be a bump including copper. The base die 10 and a bottommost intermediate die 30 of the intermediate die stack 30K may be connected to each other through the bump connection structures 215. Each of the bump connection structures 215 may be configured to include one of the second connection terminals 131 and one of the fourth connection terminals 261. In such a case, a second conductive adhesive layer 263 may be additionally disposed between the second connection terminals 131 and the fourth connection terminals 261. The intermediate dies 30 may also be electrically connected to each other through the bump connection structures 215. A non-conductive adhesive layer 300 may be disposed between the base die 10 and the intermediate dies 200. The non-conductive adhesive layer 300 may include a non-conductive film, for example.

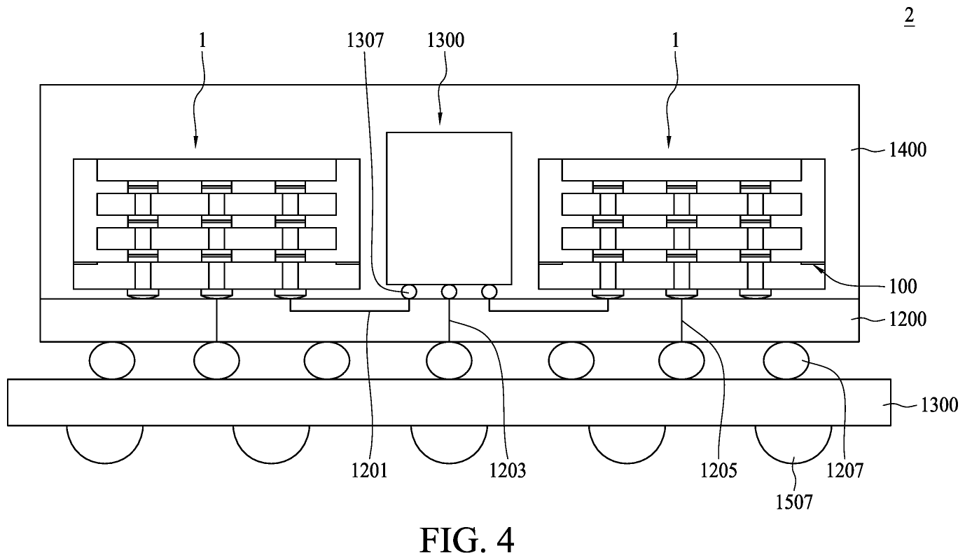

In some embodiments, at least one of the semiconductor packages 1 may be employed in another semiconductor package. For example, the semiconductor package 1 may be included in a system-in-package (SIP). FIG. 4 is a cross-sectional view depicting a semiconductor package corresponding to a system-in-package in accordance with some embodiments of the present disclosure. With reference to FIG. 4, a semiconductor package 2 may include at least one of the semiconductor packages 1 corresponding to a first semiconductor package of the semiconductor package 2. The first semiconductor package 1 may act as a package-in-package embedded in a single SIP. The first semiconductor package 1 may be mounted on an interconnect layer 1200. The interconnect layer 1200 may correspond to an interposer, for example. A semiconductor device 1300 may be disposed on the interconnect layer 1200. The semiconductor device 1300 may be a semiconductor die or a semiconductor package, for instance.

In some embodiments, the semiconductor device 1300 may be disposed on a surface of the interconnect layer 1200 and beside the first is semiconductor package 1. Another first semiconductor package 1 may be disposed on the interconnect layer 1200. The semiconductor device 1300 may be disposed between the two first semiconductor packages 1, for example. Each of the first semiconductor packages 1 may act as an HBM device. The semiconductor device 1300 may include a system-on-chip (SoC). The semiconductor device 1300 may be a processor chip that communicates with the first semiconductor packages 1 in a fast signal transmission speed through a high bandwidth interface. The processor chip acting as the semiconductor device 1300 may be an application specific integrated circuit (ASIC) chip including a central processing unit (CPU) or a graphics processing unit (GPU), a microprocessor or a microcontroller, an application processor (AP), a digital signal processing core, or an interface for signal transmission.

The semiconductor device 1300 may be connected to the interconnect layer 1200 through the fifth connection terminals 1307. Each of the fifth connection terminals 1307 may include a bump. The first semiconductor packages 1 may be connected to the interconnect layer 1200 through the first connection terminals 132 depicted in FIG. 1. A second encapsulant layer 1400 may be disposed on the interconnect layer 1200 to cover a first encapsulant layer corresponding to the encapsulant layer 50 depicted in FIG. 1 of the first semiconductor packages 1. The second encapsulant layer 1400 may also extend to cover the semiconductor device 1300. The interconnect layer 1200 may be connected to a package substrate 1500 through the sixth connection terminals 1207. Each of the sixth connection terminals 1207 may include a bump having a diameter greater than a diameter of the fifth connection terminals 1307. The seventh connection terminals 1507 may be disposed on a surface of the package substrate 1500 opposite to the interconnect layer 1200. The seventh connection terminals 1507 may electrically connect the package substrate 1500 to an external device. The seventh connection terminals 1507 may be solder balls, for example.

The interconnect layer 1200 may include the first signal paths 1201 through which signals between the first semiconductor package 1 and the semiconductor device 1300 are directly transmitted. The first signal paths 1201 may be horizontal signal paths which are disposed horizontally in the interconnect layer 1200. The interconnect layer 1200 may include the second signal paths 1203 that electrically connect the semiconductor device 1300 to the package substrate 1500. The second signal paths 1203 may be vertical signal paths which are disposed to vertically penetrate the interconnect layer 1200. The interconnect layer 1200 may include the third signal paths 1205 that electrically connect the first semiconductor packages 1 to the package substrate 1500. The third signal paths 1205 may be vertical signal paths which are disposed to vertically penetrate the interconnect layer 1200.

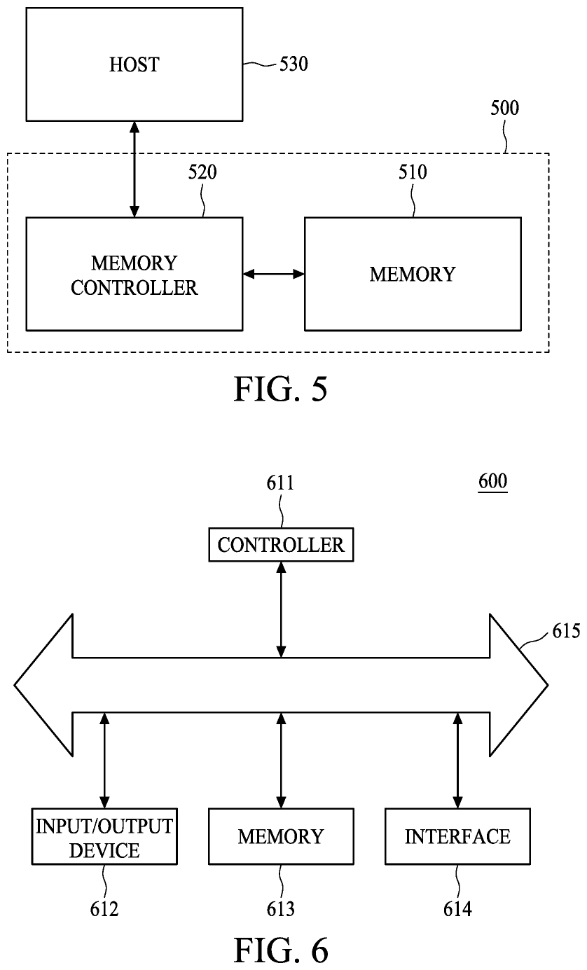

FIG. 5 is a block diagram depicting an electronic system including a memory card employing at least one of the semiconductor packages according to some embodiments of the present disclosure. A memory card 500 includes a memory 510 such as a nonvolatile memory device, and a memory controller 520. The memory 510 and the memory controller 520 may store data or read the stored data, for example. The memory card 500 may be configured to include at least one of the semiconductor packages 1 and 2 depicted FIGS. 1 and 4 in accordance with some embodiments of the present disclosure. The memory 510 may include a nonvolatile memory device to which the techniques of the embodiments of the present disclosure are applied. The memory controller 520 may control the memory 510 such that stored data is read or data is stored in response to a read/write request from a host 530.

FIG. 6 is a block diagram depicting an electronic system including at least one of the semiconductor packages according to some embodiments of the present disclosure. An electronic system 600 may include a controller 611, an input/output device 612, and a memory 613. The controller 611, the input/output device 612, and the memory 613 may be coupled with each other through a bus 615. In some embodiments, the controller 611 may include one or more of a microprocessor, digital signal processor, microcontroller, and/or logic device capable of performing the same functions as these components. The controller 611 and the memory 613 may be configured to include at least one of the semiconductor packages 1 and 2 of FIGS. 1 and 4 according to some embodiments of the present disclosure. The input/output device 612 may include at least one selected among a keypad, a keyboard, a display device, a touchscreen, and other devices. The memory 613 may be a device for storing data. The memory 613 may store data and/or commands to be executed by the controller 611.

The memory 613 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this example, the electronic system 600 may stably store a large amount of data in a flash memory system.

The electronic system 600 may also include an interface 614 configured to transmit and receive data to and from a communication network. The interface 614 may be a wired or wireless type. For example, the interface 614 may include an antenna or a wired or wireless transceiver. The electronic system 600 may be realized as a mobile system, a personal computer, an industrial computer, or a logic system performing various functions. For example, the mobile system may be any one of a personal digital assistant (PDA), a portable computer, a tablet computer, a mobile phone, a smart phone, a wireless phone, a laptop computer, a memory card, a digital music system, and an information transmission/reception system. If the electronic system 600 is capable of performing wireless communications, the electronic system 600 may be used in a communication system using a technique of CDMA (code division multiple access), GSM (global system for mobile communications), NADC (North American digital cellular), E-TDMA (enhanced-time division multiple access), WCDAM (wideband code division multiple access), CDMA2000, LTE (long term evolution), or WiBro (wireless broadband Internet).

One aspect of the present disclosure provides a semiconductor package. The semiconductor package includes a plurality of intermediate dies and an encapsulant layer. The intermediate dies are stacked on a base die, in which the edge regions of the base die are exposed. The encapsulant layer is disposed to cover side surfaces of the intermediate dies as well as a surface of the exposed edge regions of the base die. The surface of the edge regions of the base die includes an adhesion enhancement layer.

Another aspect of the present disclosure provides a semiconductor package. The semiconductor package includes a first is semiconductor package, an interconnect layer, and a semiconductor device. The first semiconductor package includes a plurality of intermediate dies, a first encapsulant layer, and a first encapsulant layer. The intermediate dies are stacked on a base die, such that the edge regions of the base die are exposed. The first encapsulant layer is disposed to cover side surfaces of the intermediate dies as well as a surface of the exposed edge regions of the base die. The surface of the edge regions of the base die includes an adhesion enhancement layer. The first semiconductor package is mounted on the interconnect layer. The semiconductor device is disposed on the interconnect layer and beside the first semiconductor package. The semiconductor package further includes a second encapsulant layer covering the first semiconductor package and the semiconductor device.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that is perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor package comprising:
a plurality of intermediate dies stacked on a base die, wherein the edge regions of the base die are exposed; and
an encapsulant layer disposed to cover side surfaces of the intermediate dies as well as a surface of the exposed edge regions of the base die,
wherein the surface of the edge regions of the base die comprises an adhesion enhancement layer.

2. The semiconductor package of claim 1, wherein the adhesion enhancement layer has one or more gaps at least partially filled by the encapsulant layer.

3. The semiconductor package of claim 1, wherein the adhesion enhancement layer comprises a hydrophilic material.

4. The semiconductor package of claim 1, wherein the hydrophilic material is silicon dioxide.

5. The semiconductor package of claim 1, wherein the adhesion enhancement layer comprises a hydrophobic material.

6. The semiconductor package of claim 5, wherein the hydrophobic material is selectively formed on different portions of the adhesion enhancement layer.

7. The semiconductor package of claim 5, wherein the hydrophobic material is a carbon-based material.

8. The semiconductor package of claim 1, wherein the side surfaces of the base die are vertically aligned with outer side surfaces of the encapsulant layer, respectively.

9. The semiconductor package of claim 1, wherein the base die and the intermediate dies form a high bandwidth memory (HBM) device.

10. The semiconductor package of claim 1, wherein the base die and the intermediate dies are electrically connected to each other by through silicon vias (TSVs).

11. A semiconductor package comprising:
a first semiconductor package comprising a plurality of intermediate dies stacked on a base die, wherein the edge regions of the base die are exposed, and a first encapsulant layer disposed to cover side surfaces of the intermediate dies as well as a surface of the exposed edge regions of the base die, wherein the surface of the edge regions of the base die comprises an adhesion enhancement layer;
an interconnect layer wherein the first semiconductor package is mounted thereon;
a semiconductor device disposed on the interconnect layer and beside the first semiconductor package; and
a second encapsulant layer covering the first semiconductor package and the semiconductor device.

12. The semiconductor package of claim 11, wherein the adhesion enhancement layer has one or more gaps at least partially filled by the first encapsulant layer.

13. The semiconductor package of claim 11, wherein the adhesion enhancement layer comprises a hydrophilic material.

14. The semiconductor package of claim 11, wherein the hydrophilic material is silicon dioxide.

15. The semiconductor package of claim 11, wherein the adhesion enhancement layer comprises a hydrophobic material.

16. The semiconductor package of claim 15, wherein the hydrophobic material is selectively formed on different portions of the adhesion enhancement layer.

17. The semiconductor package of claim 15, wherein the hydrophobic material is a carbon-based material.

18. The semiconductor package of claim 11, wherein the side surfaces of the base die are vertically aligned with outer side surfaces of the first encapsulant layer, respectively.

19. The semiconductor package of claim 11, wherein the base die and the intermediate dies form a high bandwidth memory (HBM) device.

20. The semiconductor package of claim 11, wherein the base die and the intermediate dies are electrically connected to each other by through silicon vias (TSVs).
